(19) United States
(12) Patent Application Publication
(10) Pub. No.: US 2010/0276734 A1
(43) Pub. Date: Nov. 4, 2010

(54) ELECTROCHEMICAL BIOSENSOR ARRAYS AND SYSTEMS AND METHODS OF MAKING SAME

(75) Inventors: Mira Josowicz, Atlanta, GA (US); Jiri Janata, Atlanta, GA (US); Janusz Kowalik, Atlanta, GA (US); Andreas Hierlemann, Zurich (CH); Flavio Heer, Niederglatt (CH); Kay-Uwe Kirstein, Dietikon (CH)

Correspondence Address: TROUTMAN SANDERS LLP;5200 BANK OF AMERICA PLAZA, 600 PEACHTREE STREET, N.E., SUITE 5200, ATLANTA, GA, 30308-2216, US

(73) Assignees: Georgia Tech Research Corporation, Atlanta, GA (US); Eidgenössische Technische Hochschule Zürich, Zurich (CH)

(21) Appl. No.: 12/377,587

(22) PCT Filed: Aug. 14, 2007
(86) PCT No.: PCT/US07/17888

§ 371 Date: Feb. 13, 2009

Related U.S. Application Data
(60) Provisional application No. 60/837,572, filed on Aug. 14, 2006.

(51) Int. Cl. H01L 27/092; H01L 21/28

(52) U.S. Cl. 257/253; 438/49; 257/E27.062; 257/E21.158

(57) ABSTRACT

Electrochemical biosensor arrays and systems, as well as methods of making the electrochemical biosensor arrays and systems, are described herein. The electrochemical biosensor systems can be used with CMOS detection circuits that have a plurality of chemical detection and/or actuation channels or sites. The biosensor systems generally include a first inert conducting electrode disposed on a first portion of a CMOS detection circuit and a polymeric layer adjacent the first inert conducting electrode. The biosensor systems can also include a capture biomolecule bound to the polymeric layer. The biosensor system can also include the CMOS detection and/or actuation circuit having a plurality of channels.

### CROSS-REFERENCE TO RELATED APPLICATION

The present application claims the benefit of U.S. Provisional Patent Application Ser. No. 60/837,572, filed 14 Aug. 2006, and entitled “Electrochemical Biosensor Array and System,” which is hereby incorporated by reference in its entirety as if fully set forth below.

### TECHNICAL FIELD

The various embodiments of the present invention relate generally to systems and methods for electrochemical biosensing. More particularly, the various embodiments of the present invention relate to electrochemical biosensor systems having arrays of electrochemical biosensing electrodes disposed on complementary metal oxide semiconductor (CMOS) chips, and to methods of making the electrochemical biosensor systems.

### BACKGROUND

In general, a biosensor is a device capable of identifying a target biomolecule such as a polynucleotide, polypeptide, or other biomolecule of interest. There is great interest in developing biosensors to be used for varied purposes from disease diagnostics to monitoring gene expression in organisms to identification and speciation of possible pathogens and/or biocontaminants to the identification of drug candidates. Such devices would be a great benefit for medical diagnostics, food and water safety monitoring, and defense of military and civilian populations from biological threats. Sensors developed for the detection of biological analytes are typically based on ligand specific binding events between a recognition binding pair, such as antigen-antibody, hormone-receptor, drug-receptor, cell surface antigen-lectin, biotin-avidin, and complementary nucleic acid strands. The analyte to be detected may be either member of the binding pair, or the target analyte may be a ligand analog that competes with the native ligand for binding to the complement receptor.

Traditional biosensors designed for the purpose of detecting binding events between complementary binding pairs, such as those described above, are large, and require significant volumes of liquid reagents and highly trained personnel. Typically, the reduction or elimination of any of these requirements leads to a subsequent loss of sensitivity and/or selectivity. Over the past several years researchers have been striving to develop alternatives to current biosensor technologies, but many developments have been geared to large, array-based equipment to increase sensitivity or throughput in the laboratory setting.

Examples of some of these efforts include optical biosensors that employ recognition elements to detect a target analyte, such as nucleic acid (e.g., DNA or RNA) hybridization assays. Such hybridization assays have been developed to interrogate samples for multiple analytes from a single sample. Nucleic acid based biosensors can be very selective; however, the optical techniques employed in many such sensors require multiple liquid reagents that must be stored in controlled environments and fluorescent labels that can be unstable. Labeling of biological molecules can be very expensive, tedious, and produce low yields. Also the need for optics to excite or collect fluorescent signal adds expensive and complicated components and creates alignment issues. It would be desirable to reduce the reagent load, remove the fluorescent labels, reduce manufacturing and operational costs and make the sensing element reusable and/or portable.

Biosensors incorporating electrochemical techniques were developed in order to meet some of these needs. A typical electrochemical biosensor includes a base electrode and a biochemically discriminating element in contact or otherwise coupled to the electrode. The biochemically discriminating element functions either to detect and transform the target analyte into an electrically active species, which is then detected by the electrode, or to otherwise generate an electrical signal, which is sensed and monitored by the electrode.

The application of electrochemical techniques to biosensor technology holds many advantages over optical techniques including, but not limited to, the lack of optical elements to align, the ability to operate in turbid media such as blood or waste water, as well as the ability to capitalize on the vast electronics processing industry for electrode arrays and control electronics. However, manufacture and use of such electrochemical biosensors has proven challenging due to complicated designs and electrochemical interferences caused by interactions of substances other than the target analyte.

Due to the difficulty of converting a biochemical binding event into an electrochemical signal, early applications of electrochemical biosensors were designed for detecting analytes that are themselves electrochemical species, or that can participate in reactions that generate electrochemical species, rather than to direct detection of ligand-receptor binding events. However, such sensors are quite limited in their application. In an effort to overcome this problem, sensors were developed that involve an intermediate reaction or a secondary active species of some sort, which acts to generate the electrochemical signal. One such design includes two separate reaction elements in the bio sensor: a first element contains a receptor and bound enzyme-linked ligand, and the second element includes components for enzymatically generating and then measuring an electrochemical species. In operation, analyte ligand displaces the ligand-enzyme conjugate from the first element, releasing the enzyme into the second element region, thus generating an electrochemical species that is measured in the second element. Two-element biosensors of this type are relatively complicated to produce, thus limiting their usefulness.

Biosensors that attempt to couple electrochemical activity directly to a ligand-receptor binding event without the use of two reaction elements have been proposed where a lipid bi-layer membrane containing an ion-channel receptor that is either opened or closed by ligand binding to the receptor controls access to the electrode. Electrodes of this type have been limited at present to a rather small group of receptor proteins.

Additionally, there is a need for biosensors, particularly for diagnostic purposes, which are easily portable for use in the field rather than the laboratory setting. Such a biosensor would provide many advantages for use in areas and situations where laboratory access is limited, such as in third world countries, or in situations where time does not permit sending a sample to a lab for analysis and waiting for results.

As discussed, many of the above techniques have disadvantages such as complicated design, expensive reagents and manufacturing costs, use of fluorescent tags, applicability to only a small class of biomolecules, and complicated, multi-step processing. Thus, there is a need in the industry for a biosensor that overcomes at least these disadvantages.

### BRIEF SUMMARY

Various embodiments of the present invention are directed to improved electrochemical biosensor systems. The electrochemical biosensor systems can be used with CMOS detection circuits that have a plurality of chemical detection channels or sites. The biosensor system generally includes a first inert conducting electrode disposed on a first portion of said CMOS unit that may feature detection circuitry and a polymeric layer adjacent the first inert conducting electrode. The biosensor system can also include a capture biomolecule bound to the polymeric layer. The biosensor system can also include the CMOS detection circuit having a plurality of chemical detection channels.

The first inert conducting electrode of the electrochemical biosensor system can include a noble metal, such as platinum. The first inert conducting electrode can be deposited at a location that corresponds to a first chemical detection channel of the plurality of chemical detection channels.

The polymeric layer can be electropolymerized on the first inert conducting electrode. The polymeric layer can be a polymeric monolayer or a polymeric multilayer (i.e., having two or more layers). In one embodiment, the polymeric layer can include a first layer deposited on the first inert conducting electrode and a second layer disposed on the first layer. One or more additional intermediate layers can be interposed between the first and second layers.

The second layer of the polymeric layer can be formed on the first layer using self-terminating electropolymerization. The second layer of the polymeric layer can provide attachment points for the capture biomolecule. The first layer of the polymeric layer can have an average thickness of about 0.1 to about 1.0 micrometers, while the second layer of the polymeric layer can have an average thickness of about 1 to about 10 nanometers.

The first layer of the polymeric layer can exchange ions with an introduced solution when the polymeric layer is polarized. For example, the first layer of the polymeric layer can be adapted to adsorb and/or absorb anions or expel cations from the introduced solution when a positive potential is applied to the first inert conducting electrode. The first layer of the polymeric layer can alternatively be adapted to expel anions or adsorb and/or absorb cations when a negative potential is applied to the first inert conducting electrode.

The capture biomolecule can be bound to the polymeric layer via a multivalent metal complex and/or a covalent bond. The capture biomolecule can be a first nucleic acid strand selected to identify a complementary second nucleic acid strand. The capture biomolecule can be packaged and provided separately from the polymeric layer.

The electrochemical biosensor systems can also include an evaluation component.

The evaluation component can comprise a portion of the CMOS chip, or can be external to the CMOS detection circuitry. The evaluation component can include data transfer and evaluation software protocols that are capable of transforming raw data from the biosensor into diagnostic information. This diagnostic information can be loaded onto a portable computer system, such as a palmtop or laptop computer, for ease of portability.

Other embodiments of the present invention are directed to methods of fabricating a biosensor. The methods generally include providing a CMOS detection circuit having a plurality of chemical detection channels, depositing a first inert conducting electrode on a first portion of the CMOS detection circuit, depositing a polymeric layer adjacent the first inert conducting electrode, and providing a capture biomolecule to be bound to the polymeric layer.

The methods can also include packaging the capture biomolecule separately from the polymeric layer. The methods can also include binding the capture biomolecule to the polymeric layer. Binding the capture biomolecule to the polymeric layer can comprise binding via a multivalent metal complex and/or binding via a covalent bond. The capture biomolecule can be a first nucleic acid strand selected to identify a complementary second nucleic acid strand.

The first inert conducting electrode can be deposited on the first portion of the CMOS detection circuit by depositing the first inert conducting electrode at a location corresponding to a first chemical detection channel of the plurality of chemical detection channels. The first inert conducting electrode can include a noble metal. For example, the first inert conducting electrode can be platinum.

Depositing the polymeric layer adjacent the first inert conducting electrode can encompass electropolymerizing the polymeric layer on the first inert conducting electrode. The polymeric layer can be a polymeric monolayer or a polymeric multilayer (i.e., having two or more layers). It is possible for the polymeric layer to be created by depositing a first layer on the first inert conducting electrode and then depositing a second layer on the first layer. One or more additional intermediate layers can be interposed between the first and second layers. The second layer can be deposited by self-terminating electropolymerization.

The methods can further include providing an evaluation component. Providing the evaluation component can include disposing the evaluation component on a portion of the CMOS detection circuit. Alternatively, providing the evaluation component can include providing data transfer and external evaluation software protocols that are capable of transforming raw data from the biosensor into diagnostic information. This diagnostic information can be loaded onto a portable computer system, such as a laptop computer, for ease of portability.

Other aspects and features of the embodiments of the present invention will become apparent to those of ordinary skill in the art, upon reviewing the following detailed description in conjunction with the accompanying figures.

### BRIEF DESCRIPTION OF THE FIGURES

Aspects of the disclosure can be better understood with reference to the attached drawings, described in greater detail below. The components in the drawings are not necessarily to scale, emphasis instead being placed upon clearly illustrating the principles of the present disclosure.

FIG. 1 is a block diagram illustrating a circuit incorporating an exemplary embodiment of the present invention. A repeating unit in each element of the array contains a working electrode, an amperometer, and an ADC converter. The digital control block is connected to the ADCs of the repeating units and to the potentiostat circuit via a DAC. The potentiostat circuit is connected to a reference electrode and drives the counter electrode.

FIG. 2 schematically illustrates a recognition bilayer with a probe biomolecule, which is immobilized via a salt bridge, deposited on a platinum electrode in accordance with an exemplary embodiment of the present invention.

FIG. 3 schematically illustrates the binding of a single-stranded DNA probe molecule with a complementary DNA target in accordance with an exemplary embodiment of the present invention. The charges on the respective molecules are due to the presence of the phosphate groups.

FIG. 4 is an illustration of a biosensor array in accordance with an exemplary embodiment of the present invention. The center area of the chip is exposed to the liquid sample, while the surrounding parts (i.e., those that contain the digital control block and the bond pads) are protected. The exposed area includes an array of repeating units as well as the reference and counter electrodes. Each repeating unit contains a working electrode and solid-state circuitry, such as an amperometer and an ADC.

FIG. 5 is a graph displaying data reflective of a hybridization event occurring between two DNA samples in accordance with an exemplary embodiment of the present invention.

FIG. 6 is a block diagram of an exemplary DNA CMOS chip architecture according to an exemplary embodiment of the present invention.

FIG. 7 is a micrograph of an exemplary DNA CMOS chip architecture according to an exemplary embodiment of the present invention.

### DETAILED DESCRIPTION

Before the embodiments of the present disclosure are described in detail, it is to be understood that unless otherwise indicated the present disclosure is not limited to particular materials, reagents, reaction materials, manufacturing processes, or the like, as such may vary. It is also to be understood that the terminology used herein is for purposes of describing particular embodiments only, and is not intended to be limiting. It is also possible in the present disclosure that steps may be executed in different sequence where this is logically possible.

It must be noted that, as used in the specification and the appended claims, the singular forms “a,” “an” and “the” include plural referents unless the context clearly dictates otherwise. In this specification and in the claims that follow, reference will be made to a number of terms that shall be defined to have the following meanings, unless a contrary intention is apparent.

Use of the phrase “biomolecule” is intended to encompass various forms of nucleic acids including, but not limited to, deoxyribonucleic acid (DNA), ribonucleic acid (RNA), nucleotides, oligonucleotides, nucleosides, and the like, including both natural and synthetic/modified nucleic acids. In particular, biomolecules of the present disclosure (e.g., capture biomolecules and/or the analyte to be detected) can include, but are not limited to, naturally occurring substances such as, polynucleotides, in particular single stranded DNA oligonucleotides.

Use of the phrase “polynucleotide” is intended to encompass DNA and RNA, whether isolated from nature, of viral, bacterial, plant or animal (e.g., mammalian, such as human) origin, or synthetic; whether single-stranded or double-stranded; or whether including naturally or non-naturally occurring nucleotides, or chemically modified. As used herein, “polynucleotides” include single or multiple stranded configurations, where one or more of the strands may or may not be completely aligned with another. The terms “polynucleotide” and “oligonucleotide” shall be generic to polydeoxynucleotides (containing 2-deoxy-D-ribose), to polyribonucleotides (containing D-ribose), to any other type of polynucleotide, which is an N-glycoside of a purine or pyrimidine base, and to other polymers, in which the conventional backbone has been replaced with a non-naturally occurring or synthetic backbone, or in which one or more of the conventional bases has been replaced with a non-naturally occurring or synthetic base. An “oligonucleotide” generally refers to a nucleotide multimer of about 2 to 100 nucleotides in length, while a “polynucleotide” includes a nucleotide multimer having any number of nucleotides greater than 1, although they are often used interchangeably.

Use of the term “affinity” can include biological interactions and chemical interactions. The biological interactions can include, but are not limited to, bonding or hybridization among one or more biological functional groups located on the first biomolecule and the second biomolecule. In this regard, the capture biomolecule can include one or more biological functional groups that selectively interact with one or more biological functional groups of the analyte. The chemical interaction can include, but is not limited to, bonding among one or more functional groups (e.g., organic and/or inorganic functional groups) located on the biomolecules.

The various embodiments of the present invention provide improved electrochemical biosensor instruments or systems. In contrast to existing systems, the electrochemical biosensor systems generally have arrays of electrochemical biosensing electrodes disposed on complementary metal oxide semiconductor (CMOS) chips. The various embodiments of the present invention provide inexpensive, simple, compact, portable, array-based biosensors and/or diagnostic systems, methods of making such biosensors, and methods of using the biosensors to detect a target analyte. There is a great need for this type of technology for applications including, but not limited to, medical diagnostics, military and civilian security, environmental safety, genetic mapping, and drug discovery, and a particular need for such applications in the field (or other non-laboratory) setting. The biosensors and systems of the present disclosure provide many advantages including, but not limited to, low cost of manufacture, relatively easy assembly out of inexpensive and stable reagents, low operating costs due to low-power platform, the ability to manufacture the sensor in small sizes, the ability to mass-produce the sensor platform, the ability to combine sensors or sensor arrays and readout electronics on the same chip for improving performance and for performing simultaneous multi-sensor or sensor/reference measurements, the ability to incorporate the sensor and diagnostic analysis capabilities in a portable system, and the adaptability to producing the sensors in an array format on a single chip for high-throughput applications.

In preferred embodiments of the present disclosure, the biosensor array and system of the present disclosure includes three parts: 1) an array of microelectrodes in an electrochemical configuration, preferably integrated onto a single chip (e.g., a CMOS chip), which microelectrodes may be functionalized with one or more capture biomolecules specific for one or more target analytes, and which are capable of detecting a binding event between a capture biomolecule and a target analyte without labeling; 2) dedicated, multiplexed potentiostat and signal processing circuitry serving the microelectrode array and also preferably integrated onto the same chip; and 3) data transfer and evaluation software protocol capable of transforming the raw data from the sensor into useful diagnostic information, preferably capable of being loaded onto a portable computer system, such as a laptop computer, for ease of portability. These elements will be described in greater detail below.

Additional advantages of the biosensor system and array of the present disclosure include that it provides a diagnostic tool that can be compatible with and powered from a standard laptop computer. In an embodiment, the biosensor system includes a precursor module containing an array of microelectrodes, potentiostat, electrochemical cell and dedicated solid state circuitry, integrated on the same chip that can be prepared in advance of the application and stored for prolonged period of time before use. In another embodiment, the biosensor system includes a precursor module that can be transformed into an active diagnostic mode either on-site or off-site, on an “as needed basis” by exposure to a solution of the capture biomolecule (e.g., a DNA probe molecule). The biosensor system of the present disclosure also provides label-free methodology that does not require chemical modification of the capture biomolecule or of the target analyte (e.g., target biomolecule), neither is it necessary to produce or release any chemicals upon the occurrence of a recognition event.

Embodiments of the present system are capable of providing a special electrochemical excitation signal that is optimized to yield the maximum diagnostic value. Thus, the biosensor of the present disclosure represents a complete diagnostic package with the capability to aid rapid DNA analysis, or other bio-analysis, by a person who has minimum technical training. In preferred embodiments, the raw electrochemical output from the biosensor array of the present disclosure is collected and transferred to the memory of a laptop computer, which includes a pattern recognition evaluation program that can can be trained to identify a specific hybridization event and also the degree of the matching between the capture biomolecule and the target analyte (e.g., a specific polynucleotide associated with a certain disease or condition), and thus recognize the signature of a particular disease for which it was “trained”. Thus, the biosensor array of the present disclosure provides a complete diagnostic package, whose purpose is to aid rapid screening, detection, and analysis of a target analyte, specifically a target nucleotide, without elaborate preparation, by a person who has minimum technical training and to enable portability of such a system, bringing heretofore unavailable diagnostic capabilities to remote areas.

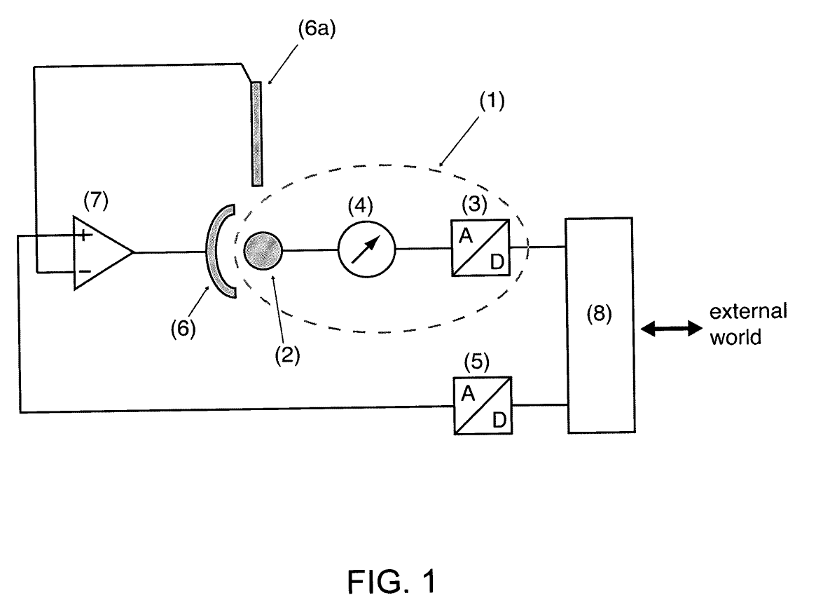

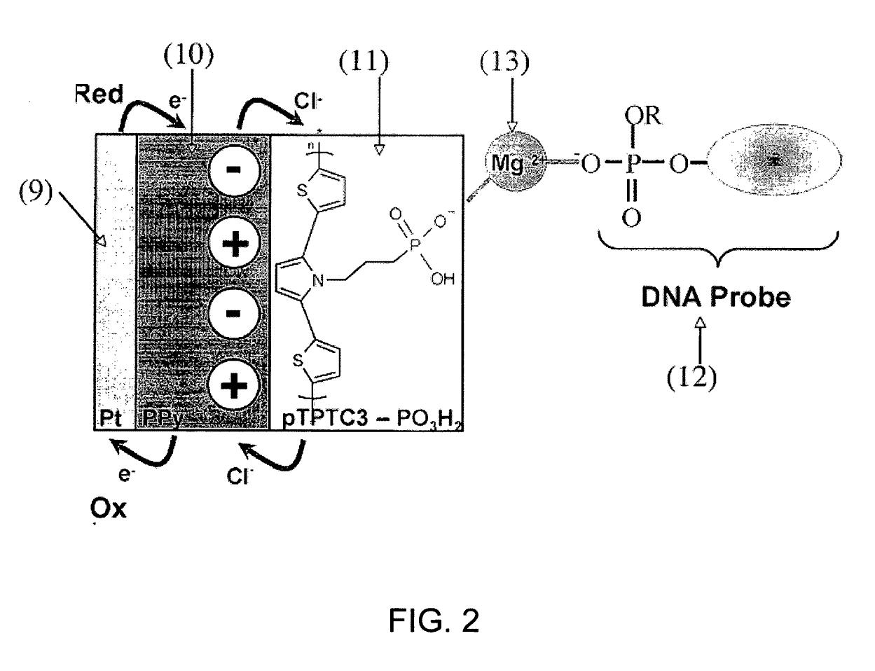

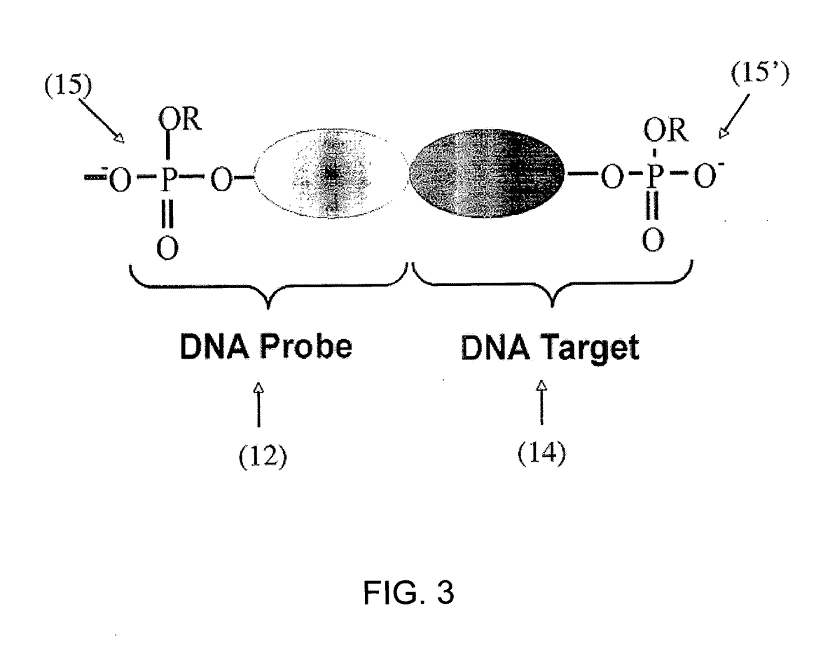

FIG. 1 generally illustrates the biosensor system of the present disclosure having a biosensor working electrode (2), which is illustrated in more detail in FIGS. 2 and 3. The working electrode (2), includes an electrode support (9), a polymeric bilayer (10, 11), and a capture biomolecule (12) that may be bound to a second (or upper) polymer layer (11) via a metal complex (13), as illustrated in FIG. 2. While reference has been made to a bilayer throughout this disclosure, those skilled in the art to which this invention pertains will recognize that a polymeric bilayer is merely one example of an exemplary polymeric multilayer. Preferably, such a polymeric multilayer is configured such that a first layer corresponds to the layer that is disposed on the electrode (9), and a second layer corresponds to the layer on which the capture biomolecule (12) is disposed. Additional layers can be disposed between the first and second layers to form a multilayer having three or more layers.

The electrode support (9) may be made of any noble electrode material. Possible materials include, but are not limited to, carbon, gold, and platinum. In a preferred embodiment, the electrode is platinum.

A polymeric bilayer (10,11) is electropolymerized on the conducting electrode (9). The ion transfer capability into and out of the bilayer is based on the electrochemically controlled exchange of the ions between the bilayer and the solution. The bilayer behavior to transfer anions is governed by the structure of its interface and by the applied potential. Simultaneously, the exchange of co-ions of the opposite polarity is hindered. Hence, the bilayer acts as electrochemically controlled anion exchanger. In preferred embodiments it is desirable that such polymer bilayer be made chemically inert, and having good adhesion to the conductive substrate.

One of the layers (10) is preferably thick (e.g., about 0.1 μm to about 1 μm) polymer, such as polypyrrole or polythiophene. When it is polarized it exchanges ions with the solution in a process called electrochemical doping. The ions exchanged are typically anions that are absorbed into the polymer when a positive potential is applied to the electrode and are expelled when a negative potential is applied. In some buffers the exchanging ions can be cations or both cations and anions. When the application of the potential is done in a cyclic manner, a cyclic voltammogram of a characteristic shape and size is obtained. A large variety of electroactive polymers can be used for this purpose, and one of skill in the art would understand various polymers that could be used for the polymer layer of the present disclosure. It is possible to use other excitation waveforms, such as “square wave cyclic voltammogram” that can enhance the interpretative potential of the electrochemical reaction. When different buffers are used the shape of the resulting CV can be different. The important point is that the same buffer (type and composition) must be used for the recognition of the hybridization event.

The second polymer layer (11) is formed (e.g., grafted/electropolymerized) on top of the first polymer. The purpose of the second polymer layer (11) is to provide sufficient attachment points for the capture biomolecule (e.g., a capture polynucleotide or “probe DNA”). An important property of this layer is that as it is grown electrochemically as a thin (e.g., about 1 nm to about 10 nm thick) layer by “self-terminating electropolymerization”. Again, many so-called “self-doped” polymers can be formed for this purpose, as would be understood by one of skill in the art. A common feature of such materials is the covalently attached acidic group that “self-dopes” the polymer. Exemplary polymers useful for this purpose include, but are not limited to, poly 2,5,-bis(2-thienyl)-N-(3-phosphorylpropyl)pyrrole (pTPTCn-PO₃H₂), which has pendant phosphonate groups that can be separated from the main polymer backbone by about 3-16 carbon atoms (C3-C16). The grafted pTPTCn-PO₃H₂ layer is preferably thin; even more preferably it is a monolayer.

The pendant phosponate group is complexed with a multivalent metal cation, typically a magnesium ion (13), to form a complex (salt): pTPTCn-PO₃HMgCl. Other metal ions with low solubility of the corresponding phosphate salt can be used, such as cations of rare earth (lanthanide) groups. The salt complex is formed at the surface of the polymer bilayer, preferably formed simultaneously on the surface of each microelectrode in the array. Additional details about the polymeric bilayer, attachment of the capture biomolecule, and electrochemical hybridization assays are described in L. A. Thompson, J. Kowalik, M. Josowicz and J. Janata, J. Am. Chem. Soc., 125 (2003) 324-325, “Label-free DNA Hybridization Sensor Based on a Conducting Polymer”; and Temitope Aiyejorun, Liz Thompson, Janusz Kowalik, Mira Josowicz and Jiri Janata, “Control of Chloride Ion Exchange by DNA Hybridization at Polypyrrole Electrode, Electrochemistry of Nucleic Acids and Proteins”, E. Palecek, F. Scheller and J. Wang, Eds., Elsevier Publishers (2005), 331-344, which are both herein incorporated by reference in their entireties.

In order to make the device a biosensor, a recognition element (e.g., a capture biomolecule (12)), is placed on the surface of the bilayer. The capture biomolecule is one half of a recognition binding pair. The other half of the recognition binding pair is the target analyte to be detected, which is generally also a biomolecule. The analyte to be detected may be either element of the recognition binding pair (e.g., the receptor or the ligand) or it may be a ligand analog that competes with the ligand for binding to the complement. Suitable recognition binding pairs include, but are not limited to, complementary nucleic acid strands. Thus, possibilities for the capture biomolecule, and the target analyte include, but are not limited to, natural or synthetic nucleotides (e.g., DNA, RNA, DNA/RNA combinations), including synthetic nucleotides having modified/synthetic bases and/or modified backbones (e.g., PNA), or a combination thereof. In an embodiment, the capture biomolecule is a capture strand of oligonucleotide, and the target analyte is an oligonucleotide, where at least a portion of the sequence of the target oligonucleotide is complementary to the capture oligonucleotide. FIG. 3 depicts a capture biomolecule (12) as a single-stranded polynucleotide that binds a complementary sequence on the target analyte (14), shown as a DNA molecule. The interfacial charge that is being modulated by the binding event is due to the phosphate groups (15).

In some embodiments of the system of the disclosure, the array of microelectrodes is prepared and packaged as a precursor module without the capture biomolecule attached, so that it can be stored for long periods of time until use. At the time of use, the precursor module can be transformed into a sensor/diagnostic module by functionalization with a capture biomolecule. In preferred embodiments, the precursor module can be functionalized by exposing the microelectrode array to a solution of capture oligonucleotide (e.g., DNA probe molecules). As described below, this can be done without chemical modification of the capture oligonucleotide, thus enabling it to be done by someone with minimal technical training.

The capture biomolecule (12), such as an oligonucleotide strand that is complementary to a target analyte (14), e.g., a target oligonucleotide, is attached to the individual sensing sites by exposing to the solution of the capture biomolecule. The capture biomolecule is attached to the multivalent metal cation (13) via the second available bond to form a surface-immobilized complex of the form, e.g., [pTPTCn-PO₃H₂-M-phosphate-DNA]. This procedure is repeated for every element of the array, with immobilized capture biomolecules of choice. It can be done on a large scale “off-site” to prepare a pre-fabricated or a custom-designed array, or it can be done “on-site”, using manual deposition to allow for greater flexibility of use and design. The trade-off is the efficiency of preparation (large scale, off-site) vs. flexibility (manual, on-site). In either case, additional chemical reactions, aside from the complexation reaction, are not required.

In an embodiment of the biosensor system illustrated in FIG. 1, the working electrode is prepared according to the embodiments described above and integrated into an electrochemical system including a counter/auxiliary electrode (6) and a reference electrode (6a). The three-electrode cell can be immersed in an electrolyte of a buffer solution containing ions (e.g., chloride ions). The reference (6a) and counter electrodes (6) may be made of various conductive materials, just as the working electrode, as discussed above. In some embodiments, the counter electrode is platinum and the reference electrode is bare Ag coated with AgCl. In embodiments, the concentration of chloride ion in the buffer is constant and thus a liquid junction reference electrode is not required, providing a significant advantage.

The three electrodes are integrated with/coupled to an electrochemical workstation that provides a current or voltage source to the three electrode cell. This provides a flow of electrons to the three-electrode cell that is monitored and measured at the workstation by a signal element, which reports and records the voltammetric current.

The workstation may provide a voltage source to the electrode and measure a current, but it is also capable of working in reverse providing a current source and measuring a voltage. Either set up is acceptable for operating the biosensor of the present disclosure. FIG. 1 merely represents one possible embodiment of the biosensor and accompanying electrochemical system according to this disclosure, and other arrangements and embodiments would be known to those of skill in the art and are intended to be covered by the disclosure and claims.

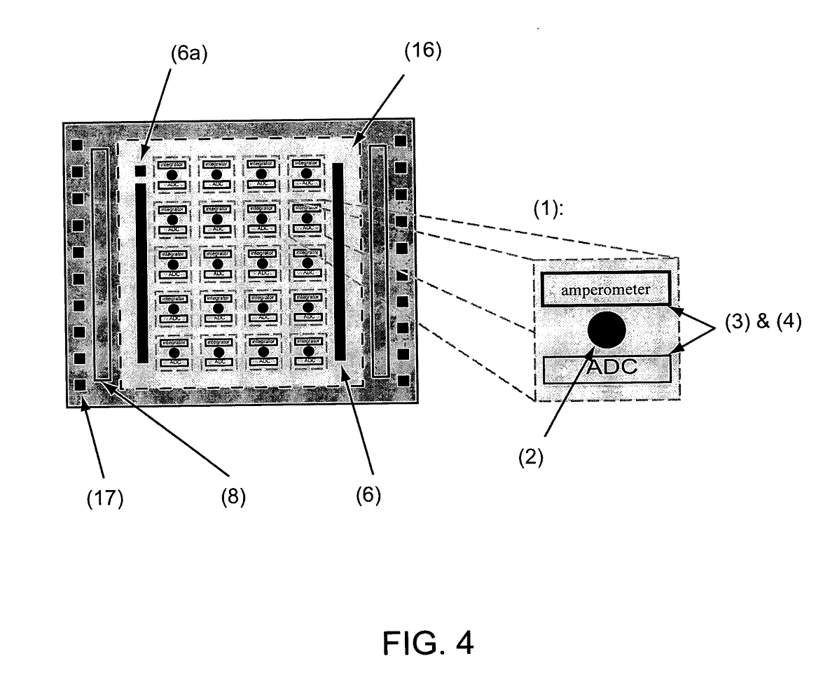

As described above, the prepared electrode array is incorporated into an electrochemical system including a current source for providing a flow of electrons to drive the electrochemical reaction and a signal element for detecting and reporting a change in the resulting voltammogram. The system also preferably includes a reference and counter/auxiliary electrode, and various other standard elements of an electrochemical system as depicted in an embodiment illustrated in FIG. 1 and briefly described above. The above-described elements of the electrochemical system are preferably integrated onto a single substrate or chip (e.g., a CMOS-chip), which also contains the array described above; an embodiment of such an array integrated on a chip is illustrated in FIG. 4. Preferably, the signal element is also capable of recording changes in the voltammogram, and thus assessing the degree of the binding of the complementary biomolecule from the features of the voltammogram. This is accomplished using various standard electrochemical techniques known to those of skill in the art, some of which are discussed in greater detail below.

In some embodiments the signal element and controlling unit of the measurement (e.g., a personal computer (PC), such as a laptop computer) also records the change in the voltammogram. The current source, signal element, and electrode array of the biosensor may be set up in a variety of configurations, in combination with other standard components of an electrochemical system (such as reference and counter/auxiliary electrodes), that will be known to those of skill in the art. These elements and other aspects of the electrochemical system, in which the biosensor operates, will be discussed in greater detail below. Preferably the electrode array, and the other circuitry elements of the electrochemical cell system are integrated on a single chip, and the signal element is a PC, preferably a portable PC such as a laptop or palmtop computer, that includes the data transfer and evaluation software capable of storing and analyzing the recorded signals.

In some embodiments of the biosensor array of the present disclosure the integrated circuit includes three general functional elements, described below and illustrated schematically in FIG. 1.

One functional element includes a potentiostat circuit that provides a regulated voltage to the counter electrode (6). The sensed input is connected to a reference electrode (6a), which can either be integrated on-chip or be realized as an external electrode. The potentiostat circuitry (7) constitutes only a basic implementation of the electrochemical system shown in FIG. 1. The integration of such a potentiostat in an electronic system is described in patent documents WO04029610A1 and WO04102211A1, which are hereby incorporated by reference in their entireties. For this purpose, the input (set-point) of the potentiostat can be connected to an integrated digital-to-analog converter (DAC) to enable automated voltammetric recording.

Another element includes the working electrode directly connected to a current-sensitive instrumentation circuit, which generates current data-matrices A and B, respectively (as described below). FIG. 1 shows this unit (1) containing the working electrode (2), the amperometer (4) and an AD converter (3) repeated in each element. It is also possible that several units share a common AD converter. The amperometer (4) is the preferred embodiment of a high-resolution current-sensitive interface to the AD-converter (3). The output of the current-sensitive instrumentation unit is also preferably integrated on a chip with the array, thus generating the data for matrices A′ and B′. This circuit block also preferably has a substantially low input impedance to ensure a stable voltage level of the working electrode. The amperometer (4) can be implemented as a current-to-voltage converter or a current-to-current converter depending on the architecture of the AD converter. Examples for this amperometer are a trans-impedance amplifier, a current conveyor, or an integrator. The implementation of a current-sensitive input, which is directly connected to the working electrode of an electrochemical setup, is superior to existing commercial systems. This approach reduces both, area and power consumption, which are important issues in developing sensor arrays featuring a large number of readout channels. Additionally, a monolithic implementation reduces the noise from electromagnetic interference. For such devices, the needed circuit area (production costs) and the overall power dissipation (self-heating) are minimized.

A third element includes a digital control block and data interface (8) providing a robust and easy-to-use interface to an external computer system. The external computer system controls the operation of cyclic voltammograms, stores the measurement data and performs the necessary data post processing and pattern recognition or data analysis tasks.

The combination and implementation of the above-described individual functional blocks of the CMOS-based biomolecule (e.g., DNA) analysis system into a complete and versatile electrochemical analysis system has not been accomplished with existing technology. This holds particularly true for a monolithic realization on a single chip. Advantages of a single-chip-voltammetry system include, but are not limited to, the possibility to integrate a large number of microelectrodes on a small-area device, to perform simultaneous measurements on the multiple microelectrodes, or to realize complex differential measurements assigning reference and measurement electrodes in the array on the same chip. This not only provides extended analysis capabilities in a very short overall analysis time, but also facilitates developing a portable device for bio-analysis that is robust enough to be fieldable, e.g., to be applied outside of laboratory facilities, which holds great promise, in particular, for the application to detect diseases in a point-of care situation or in technologically less developed countries. The realization of a multi-analysis approach on a CMOS-based microchip also holds the potential for a very cost-efficient screening device in comparison to state-of-the-art methods used in a laboratory.

FIG. 4 shows a layout sketch (floor plan) of an embodiment of a microchip featuring a monolithic integration of the above described elements. In the center area of the microchip an array of instrumentation units (1) is located, containing working electrodes (2) and solid-state instrumentation and signal conditioning circuitry (3) and (4). This array, together with the integrated reference (6a) and counter (6) electrodes, forms the area that is exposed to a liquid sample. The surrounding/peripheral part of the chip is protected against sample exposure and may contain the digital control and interface circuit block (8) and bond pads (17) for electrical connection of the chip to the outside world.

The CMOS-based microchip can be produced, for example, by covering the non-sensor area with a mask to prevent damage to the electronics. Next, the inert electrode material can be placed on the array of channels to form the array of electrodes. Then, the sensor area of a CMOS detection circuit can be protected with a mask to prevent damage to the array of electrodes. The non-sensing portion of the CMOS detection circuit (i.e., the portion not covered by the mask) can be coated with a layer of a protective material, such as an epoxy. Once the protective material has been deposited on the non-sensing area, the mask can be removed from the array of electrodes. After the inert electrode material has been disposed on the array of channels and after deposition of the protective or epoxy layer on the electronics part, the polymeric bilayer can be deposited on the inert electrode material. Finally, the capture biomolecule can be deposited on the polymeric bilayer.

In some preferred embodiments of the above-described biosensor array and integrated electrochemical system, a cyclic voltammogram is recorded in an exchanging-ion(s)-containing buffer, individually for every element of the modified array and stored in the computer memory as matrix (A). For this step a common auxiliary electrode and common reference electrodes are used. For the hybridization assay, the sample solution is applied to the electrode array between about 2 min and about 30 min. The hybridization reaction takes place according to the degree of matching of the probe and the target DNA. The array is then rinsed in the same buffer, individual electrochemical measurements are again performed, and the results are stored in the computer memory as matrix (B).

The process described above can be performed on a platform that accommodates tens of individually modified electrodes (e.g., microelectrodes). Then, diagnostic information is obtained from the collective response of the array (multivariate analysis), involving all elements of the array or, optionally, only a selected number of array elements.

In preferred embodiments, the system accommodates the modified electrode in every channel of the array and is thus able to conduct the voltammetric measurements in a microelectrode format. In such embodiments, the counter electrode and the reference electrode, which form part of an electrical circuit can be common. In some embodiments, an array of readout electronics is connected to an array of counter electrodes to record electric current through such array of counter electrodes. The system also preferably includes a dedicated electronic circuit that can collect the voltammetric data in digital form for the electrochemical measurement. In preferred embodiments, the substrate includes one or more microstructured sites including one or more working microelectrodes as described above. The microstructured sites preferably include a wall for forming one or more wells, into which the solutions of capture biomolecule can be applied for functionalizing the working electrode(s), as described above. In embodiments, the wall forming the well is from about 100 micrometers (μm) to about 200 μm in height.

In embodiments of the biosensor system of the present disclosure, an array of measurement sites/working electrodes is integrated on a single substrate/chip. In an exemplary embodiment, the substrate is a CMOS-chip. In embodiments, the substrate/chip has the capacity to accommodate hundreds of channels, and the electrodes can be spaced such that the depletion layers do not overlap (e.g., greater than about 10 μm between working electrodes). Also preferably, the active electrode size is between about 10 μm to about 20 μm by about 10 μm to about 20 μm.

In preferred embodiments, an evaluation component, including, for example, solid state electronics (including, e.g., a potentiostat circuit connected to working and reference electrodes) as described above for performing electrochemical measurements are also integrated on the same single substrate (e.g., CMOS-chip). Preferably, the system can perform cyclic voltammetry in a range of about ±0.5V. In some embodiments, the solid-state electronics are configured to set a defined electrical potential to the working electrode, or array of working electrodes. Preferably, the biosensor system is capable of providing individual current readouts for each electrode of the microelectrode array, and is programmable for parallel or group serial operation. The biosensor system also preferably includes integrated cooling/heating features to enable temperature-dependent signal acquisition and includes an on-chip passivation to allow electrolyte exposure only to the microelectrode array portion of the chip.

As mentioned above, preferably the biosensor system also includes integration of an ADC. In embodiments, the ADC includes a modular architecture to record the current signal of the counter electrodes and to convert it into the digital domain. In some embodiments the modular integrated ADC architecture includes an analog integrator with current-mode input, a set of comparators for comparing the output of the integrators to reference signals, and a digital counter, triggered by the comparator signal.

In some embodiments the ADC is integrated via circuit architecture to convert the recorded analog current signal of each measurement site into the digital domain. In embodiments of such an integrated ADC circuit architecture, the ADC architecture can share parts of the digital counter for a large number of readout channels, containing analog integrators and comparators as described above for the modular architecture. In some embodiments of such an integrated ADC circuit architecture, the working electrode and the AD converter are combined into a hybrid delta-sigma ADC. In some embodiments, the biosensor array having integrated solid-state electronics further includes a DAC, which is preferably connected to the input of the integrated potentiostat circuit. The biosensor system may also include a digital (serial) communication interface configured to set the target potential via the DAC and send the recorded current to an external recording device or computer.

As mentioned above, the biosensor/bioanalysis system further includes a data analysis component (e.g., data analysis software on a computer system coupled to the integrated electrochemical array described above). Preferably, such data analysis component/software has the ability to create difference voltammograms by subtraction of matrices B and A (described above) to create a matrix C. The data analysis component also has the ability to integrate the current in matrices A and B, thus forming charge matrices A′ and B′ and to subtract them to create matrix C′. This component also preferably has the ability to record the time evolution of matrix C and C′. In embodiments, the data analysis component includes shape recognition analysis, allowing training using all available parameters, namely C and C′ and their time evolution matrices. The information can be enhanced by using temperature-dependent/variable measurements and the respective signal differences. The data analysis component can present the results in simple diagnostic terms and provide authenticated access to raw electrochemical data.

Those of skill in the art will also appreciate that the sensing portion of the biosensor of the present disclosure (e.g., the prepared electrode/electrode array chip) can be reused. The bound analyte can be removed and the sensor reused to detect the same analyte in a different sample. Alternatively, the capture biomolecule can also be easily removed, and a new capture biomolecule added to use the biosensor for detecting a different analyte. Those of skill in the art will also understand that the biosensor of the present disclosure, prepared in an array format, can be adapted to detect many different analytes and used for high throughput applications.

Embodiments of this disclosure also include methods of using the biosensor of this disclosure to detect a target analyte in a sample to be analyzed. A biosensor is made according to the methods described above with a working electrode having a polymeric bilayer coating thereon and a capture biomolecule (e.g., a capture polynucleotide) attached thereto. Preferably the biosensor is in an array format, with multiple such working electrodes, each having a polymeric bilayer and one or more capture biomolecules coupled thereto. The capture biomolecule selected is one half of a recognition binding pair with the analyte to be detected. In some embodiments, each working electrode in the array has the same capture biomolecule, and in other embodiments one or more of the working electrodes may have different capture biomolecules than one or more of the other working electrodes, thereby enabling the biosensor to detect more than one different target analyte in a sample simultaneously.

The biosensor also includes signal processing circuitry, as discussed above. The electrode is then immersed in a sample to be analyzed (e.g., in sufficient contact with the sample for a target analyte contained in the sample to bind to the capture biomolecule) and the system is interrogated using standard electrochemical techniques. As discussed above, the biosensor also preferably includes a current source to provide a flow of electrons to drive the electrochemical processes at the electrode and a signal element for detecting and reporting any change at the electrode. As discussed above, some embodiments of the biosensor system also include a software program for storing and evaluating the electrochemical signal produced by the biosensor-chip array.

Although the present embodiments have been described with reference to cyclic voltammetry, various electrochemical techniques can be employed in such a system including, but not limited to, various forms of voltammetry, impedance and amperometry, such as cyclic voltammetry, AC voltammetry, AC impedance, square wave voltammetry and differential pulse voltammetry. Most of the above techniques may all be applied with the same electrochemical set up, but with different characteristics to the applied and measured voltages and currents. Any differences to the electrochemical set up that would be required to implement a different electrochemical technique would be understood by those of skill in the art and are intended to be included in the scope of the disclosure.

Having generally described electrochemical biosensors according to the present disclosure and methods of making and using such biosensors, some examples are provided below. While embodiments of the biosensor and methods of making and using the biosensor are described herein, there is no intent to limit embodiments of the disclosure to these examples. On the contrary, the intent is to cover all alternatives, modifications, and equivalents included within the scope of the disclosure.

### Examples

### Example 1

The electrically conducting polypyrrole (PPy) (illustrated as (1) in FIG. 2) was electropolymerized from acetonitrile solution containing 0.1 M pyrrole and 0.1 M tetrabutylammonium perchlorate (TBPA). On this PPy-layer, a pTPTC3-PO₃H₂ layer (shown as (2) in FIG.2) was polymerized from acetonitrile containing 4 mM 2,5-bis(2-thienyl)-N-(3-phosphorylpropyl)pyrrole, (TPTC3-PO₃ H₂). Both polymerizations were carried out at a constant potential of 0.8 V vs. the Ag/Ag⁺ reference electrode. The polymers were deposited at two different thicknesses; the PPy layer that controls the electrochemically driven anion-exchange was thicker than the pTPTC3-PO₃H₂ layer, which serves to link the phosphonate groups at the surface of the modified electrode to the divalent magnesium cation, shown as (13) in FIG. 2.

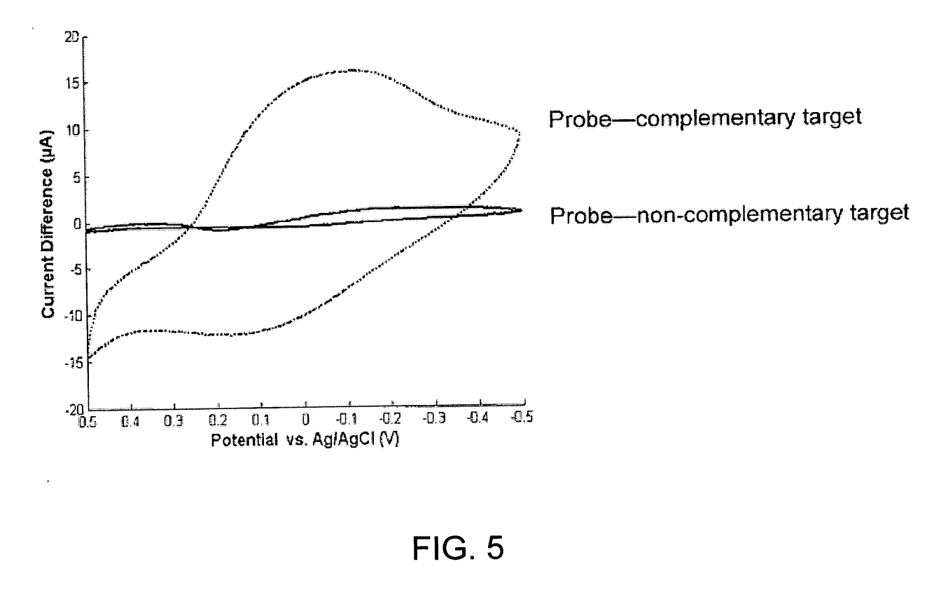

The magnesium cation was grafted onto the PPy-pTPTC3-PO₃H₂ by soaking the modified electrode in 5 mM MgCl₂ solution for a few minutes (e.g., about 5 to about 10 minutes). After that the electrode was rinsed carefully with phosphate buffer (e.g., TRIS (Tris(hydroxymethyl)aminomethane)). The electrode was then soaked in the solution containing the capture biomolecule (hereinafter “PROBE DNA”) for a few minutes (e.g., about 5 to about 30 minutes). After rinsing the electrode with the TRIS-HCl buffer, cyclic voltammograms (CV) between about 0.5 V and about −0.5 V vs. the Ag/Ag⁺ electrode were recorded in a TRIS-HCl buffer. The same electrode was then soaked in a solution containing a target analyte (hereinafter “TARGET DNA”) for a few minutes (e.g., about 5 to about 30 minutes). After washing with the TRIS buffer solution, the electrode was transferred into the electrochemical cell and the final CV was recorded as described above. Subtracting the CVs of the electrode recorded after reacting the DNA PROBE with the DNA TARGET from the first CV of the DNA PROBE only, information about the hybridization event taking place between the two DNA samples was obtained, as shown in FIG. 5.

The reliability of the electrochemical label-free DNA hybridization detector was tested with oligodeoxynucleotides (ODN) of different lengths (about 27 to about 200 bases), different sequences, and concentrations in the range of about 0.1 fM to about 10 μM.

### Example 2

In this example, a DNA CMOS chip is described. The DNA CMOS chip was a fully-integrated 24×24 array of platinum electrodes that were configured to perform electrochemical recordings (e.g., cyclic voltammetry) to detect DNA hybridization events.

The DNA CMOS chip included a 24 by 24 electrode array with about a 100 μm pitch and 24 readout channels. The electrode arrangement was defined in the post-processing and can be changed, for example, to have a larger pitch. A pitch of about 200 to about 300 μm was also used. In one measurement cycle all electrodes in one column were recorded concurrently. The required number of measurement cycles is given by the number of columns, which was 24. The voltage was applied using an external potentiostat. On-chip reference and counter electrodes can be connected, and an on-chip potentiostat for testing was included in this design.

Three different designs of readout channels, to record the electrochemical current, were integrated on the chip. Two thirds of the array can be recorded with a sigma-delta analog-to-digital converter. Two different sigma-delta converters have been designed, one using a rather simple approach and a second one using offset-canceling techniques. A third design includes a current conveyor and a time-based analog-to-digital converter.

All digital circuits were located off the chip on a field-programmable gate array (FGPA) except for an on-chip register. This provided more flexibility in using the chip and finding the right parameters for its operation. The digital part on the FPGA can be included on the chip. The shift register stores all settings to operate the chip in the required state and also allows various test modes.

The voltage ramps can be realized using an external potentiostat. A digitally programmable on-chip potentiostat can be integrated on the chip. The on-chip reference and counter electrodes can also be connected from outside for testing. Other optional components include at least two temperature sensors within the array, biasing circuits, test circuits, and the like.

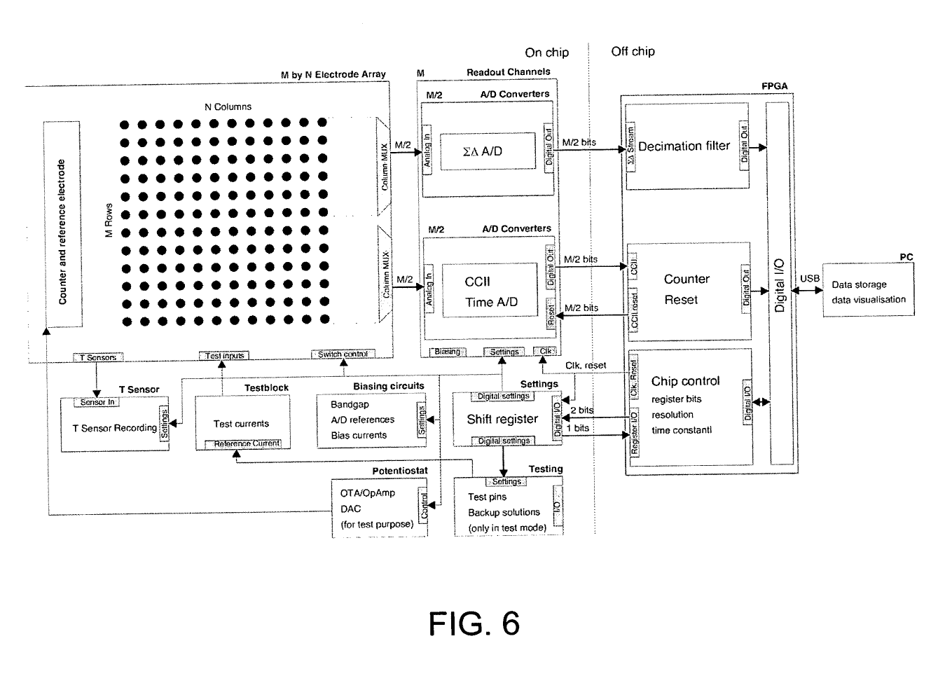

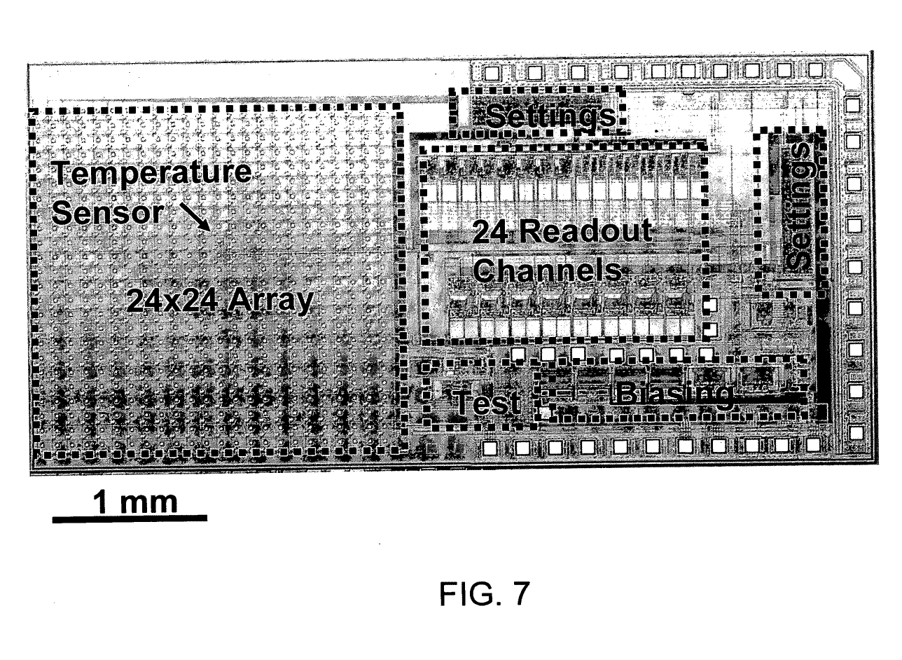

FIGS. 6 and 7 represent a block diagram and a micrograph of an exemplary DNA CMOS chip architecture, respectively. The array of 24×24 electrodes is located on the left of the chips with all circuitry and input/output (I/O) pads placed on the right side of the chip. Only about ten digital I/O pads and supply pads are necessary for a minimal chip operation with 16 readout channels, while the rest can be optionally included for either more readout channels or testing purposes.

It should be recognized by those skilled in the art to which this disclosure pertains that exemplary embodiments of the present invention are directed to biosensors for detecting target analytes. The biosensors of the present disclosure include a substrate and an array of at least two repeating units on the substrate, where each repeating unit includes a working microelectrode having an electrode support, a first polymer layer adjacent to the electrode, a second polymer layer adjacent to the first polymer layer, and one or more capture biomolecules coupled to the surface of the second polymer layer, where the capture biomolecules are specific for one or more target analytes and where the biosensor is capable of detecting a binding event between a capture biomolecule and a target analyte. The biosensors of the present disclosure also include a reference electrode, a counter electrode, and potentiostat and signal processing circuitry serving the microelectrode array. In exemplary embodiments, each repeating unit further includes an amperometer and an AD converter. Preferably, the array of microelectrodes, the reference electrode, the counter electrode, the potentiostat circuitry and the signal processing circuitry are integrated on a single substrate. The substrate is desirably a microchip.

In some exemplary embodiments, the biosensor described above is coupled to an electrochemical workstation that provides a current or voltage source to the electrodes to provide a flow of electrons to the biosensor that is monitored and measured at the workstation by a signal element, which reports and records the voltammetric current. The voltammetric current, and changes therein, can be recorded as a cyclic voltammogram. In exemplary embodiments, the signal element is a computer system including data transfer and evaluation protocol capable of transforming raw data from the biosensor into information regarding the presence and/or absence of a target biomolecule. The signal element is capable of providing diagnostic information regarding the target biomolecule. The signal element can be a palmtop or portable PC that includes data transfer and evaluation software capable of storing and analyzing the recorded signals.

The capture biomolecule can be coupled to the second polymer layer via a metal complex. In exemplary embodiments, the first polymer layer is polypyrrole or polythiophene. The second polymer can be a “self-doped” polymer, e.g., poly 2,5,-bis (2-thienyl)-N-(3-phosphorylpropyl)pyrrole (pTPTC3-PO₃H₂). In some embodiments, the second polymer layer includes a pendant phosponate group, where the pendant phosponate group is complexed with a multivalent metal cation (e.g., a magnesium ion) to form a complex. In exemplary embodiments, the capture biomolecule is an oligonucleotide strand, and the target analyte is a complementary oligonucleotide strand.

Embodiments of the present disclosure also include methods of making the biosensor of the present disclosure. Methods of making the biosensor include: providing a substrate having an array of at least two repeating units on the substrate, where each repeating unit includes a working microelectrode having an electrode support; polymerizing a first polymer layer adjacent to the electrode; polymerizing a second polymer layer adjacent to the first polymer layer; exposing the biosensor to a solution of the capture biomolecule; and allowing the capture biomolecule to attach to the second polymer layer. In exemplary embodiments the second polymer layer includes a pendant phosponate group and the method further includes functionalizing the second polymer layer with a multivalent metal cation, such that the capture biomolecule attaches to the multivalent metal cation to form a surface-immobilized complex.

Embodiments of the present disclosure also include methods of using the biosensor of the present disclosure to detect a target analyte. In embodiments of the methods of using the biosensor the biosensor described above is contacted with a solution including an electrolyte of a buffer solution containing ions; a flow of electrons is provided to the biosensor; a voltammetric current is monitored and reported by a signal element coupled to the biosensor; the biosensor is contacted with a second solution including an electrolyte of buffer solution containing ions and a target analyte; the voltammetric current is monitored and reported by a signal element coupled to the biosensor; and any change in the voltammetric current is monitored and reported by a signal element coupled to the biosensor, a specific change in the voltammetric current indicating a binding event and the presence of the target analyte.

It should be emphasized that the above-described embodiments are merely possible examples of implementations. Many variations and modifications may be made to the above-described implementations and embodiments. All such modifications and variations are intended to be included herein within the scope of this disclosure.

1-66. (canceled)

67. A biosensor system for use with a CMOS detection and/or actuation circuit having a plurality of chemical detection channels, the biosensor system comprising:
a first inert conducting electrode disposed on a first portion of said CMOS detection and/or actuation circuit; and
a polymeric layer adjacent the first inert conducting electrode.

68. The biosensor system of claim 67, further comprising a capture biomolecule bound to the polymeric layer.

69. The biosensor system of claim 68, wherein the capture biomolecule is bound to the polymeric layer via a multivalent metal complex and/or via a covalent bond.

70. The biosensor system of claim 68, wherein the capture biomolecule is a first nucleic acid strand selected to identify a complementary second nucleic acid strand.

71. The biosensor system of claim 68, wherein the capture biomolecule is packaged and provided separately from the polymeric layer.

72. The biosensor system of claim 67, further comprising a CMOS detection and/or actuation circuit having a plurality of chemical detection channels.

73. The biosensor system of claim 72, wherein the first inert conducting electrode is deposited at a location corresponding to a first chemical detection channel of said plurality of chemical detection channels.

74. The biosensor system of claim 67, wherein the polymeric layer is a polymeric multilayer.

75. The biosensor system claim 74, wherein a first layer of the polymeric multilayer exchanges ions with an introduced solution when the polymeric multilayer is polarized.

76. A biosensor system, comprising:
a CMOS detection and/or actuation circuit having a plurality of chemical detection channels;
a first inert conducting electrode disposed on a first portion of said CMOS detection and/or actuation circuit;
a polymeric multilayer adjacent the electrode; and
a capture biomolecule adapted to be bound to the polymeric multilayer.

77. The biosensor system of claim 76, wherein the first inert conducting electrode is deposited at a location corresponding to a first chemical detection channel of said plurality of chemical detection channels.

78. The biosensor system of claim 76, wherein the capture biomolecule is bound to the polymeric multilayer via a multivalent metal complex and/or via a covalent bond.

79. The biosensor system of claim 76, wherein a first layer of the polymeric multilayer exchanges ions with an introduced solution when the polymeric multilayer is polarized.

80. The biosensor system of claim 76, wherein the capture biomolecule is a first nucleic acid strand selected to identify a complementary second nucleic acid strand.

81. The biosensor system of claim 76, wherein the capture biomolecule is packaged and provided separately from the polymeric multilayer.

82. The biosensor system of claim 76, further comprising an evaluation component.

83. The biosensor system of claim 82, wherein the evaluation component comprises a portion of the CMOS detection circuit.

84. A method of fabricating a biosensor, the method comprising:
providing a CMOS detection and/or actuation circuit having a plurality of chemical detection and/or actuation channels;
depositing a first inert conducting electrode on a first portion of the CMOS detection circuit;
depositing a polymeric layer on the first inert conducting electrode; and
providing a capture biomolecule to be bound to the polymeric layer.

85. The method of claim 84, wherein depositing the first inert conducting electrode on the first portion of the CMOS detection circuit comprises depositing the first inert conducting electrode at a location corresponding to a first chemical detection channel of the plurality of chemical detection channels.

86. The method of claim 84, further comprising packaging the capture biomolecule separately from the polymeric layer.
